(19) United States
(12) Patent Application Publication
(10) Pub. No.: US 2026/0322357 A1
(43) Pub. Date: Oct. 15, 2026

(54) Multi-Gain Mode Filter with Improved Linearity

(71) Applicant: Apple Inc., Cupertino, CA (US)

(72) Inventor: Fei Wang, Sunnyvale, CA (US)

(21) Appl. No.: 19/177,176

(22) Filed: Apr. 11, 2025

(51) Int. Cl. H03H 11/04; H03F 3/45

(52) U.S. Cl. CPC H03H 11/0427; H03F 3/45475; H03H 2210/017; H03H 2210/021

(57) ABSTRACT

Wireless circuitry is provided that includes multiple receive paths and a filter circuit configured to receive signals from the multiple receive paths. The filter circuit can include a transconductance circuit. The transconductance circuit can include pull-down transistors having two or more different threshold voltages. The transconductance circuit can further include pull-up transistors having two or more different threshold voltages. Programmable current sources and programmable resistors can be coupled to the source terminals of the pull-down and pull-up transistors and can be selectively tuned depending on whether the transconductance circuit is operating in a first gain mode or a second gain mode. The pull-down and pull-up transistors can have adjustable drivability.

### FIELD

This disclosure relates generally to electronic devices and, more particularly, to electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

A receiver in the transceiver circuitry can include a baseband filter. The baseband filter can include a transconductance cell configured to provide high input impedance to avoid loading the prior stage. It can be challenging to design a transconductance cell with stable linearity for the receiver.

### SUMMARY

An aspect of the disclosure provides a wireless receiver that includes a plurality of receive paths and a filter circuit configured to receive signals from the plurality of receive paths. The filter circuit includes a transconductance circuit. The transconductance circuit includes a first pull-down transistor having a first threshold voltage and a second pull-down transistor coupled in parallel with the first pull-down transistor and having a second threshold voltage different than the first threshold voltage. The transconductance circuit can further include a third pull-down transistor coupled in parallel with the first and second pull-down transistors and having a third threshold voltage different than the first and second threshold voltages, where the first, second, and third pull-down transistors have gate terminals coupled to a first input terminal of the transconductance circuit.

The transconductance circuit can further include a fourth pull-down transistor having the first threshold voltage, a fifth pull-down transistor coupled in parallel with the fourth pull-down transistor and having the second threshold voltage, and a sixth pull-down transistor coupled in parallel with the fourth and fifth pull-down transistors and having the third threshold voltage, wherein the fourth, fifth, and sixth pull-down transistors have gate terminals coupled to a second input terminal, different than the first input terminal, of the transconductance circuit. The transconductance circuit can further include a first programmable current source coupled to source terminals of the first, second, and third pull-down transistors and a second programmable current source coupled to source terminals of the fourth, fifth, and sixth pull-down transistors. The transconductance circuit can further include a first programmable resistor having a first terminal coupled to the first programmable current source and having a second terminal coupled to a node, a second programmable resistor having a first terminal coupled to the second programmable current source and having a second terminal coupled to the node, and a third programmable current source coupled to the node.

An aspect of the disclosure provides a transconductance circuit that includes: a first pull-up transistor having a source terminal, a drain terminal that is coupled to a first output terminal, and a gate terminal that is configured to receive an input signal, where the first pull-up transistor has a first threshold voltage; a second pull-up transistor having a source terminal shorted to the source terminal of the first pull-up transistor, a drain terminal shorted to the drain terminal of the first pull-up transistor, and a gate terminal that is configured to receive the input signal, where the second pull-up transistor has a second threshold voltage different than the first threshold voltage; and a first programmable current source having a first terminal coupled to the source terminals of the first and second pull-up transistors and having a second terminal coupled to a positive power supply line. The transconductance circuit can further include a third pull-up transistor having a source terminal shorted to the source terminal of the first pull-up transistor, a drain terminal shorted to the drain terminal of the first pull-up transistor, and a gate terminal that is configured to receive the input signal, where the third pull-up transistor has a third threshold voltage different than the first and second threshold voltages.

An aspect of the disclosure provides a transconductance circuit that includes: a first programmable pull-down switch having a gate terminal configured to receive an input signal, where the first programmable pull-down switch has a first threshold voltage and is adjusted to provide a first drive strength; and a second programmable pull-down switch coupled in parallel with the first programmable pull-down switch and having a gate terminal configured to receive the input signal, where the second programmable pull-down switch has a second threshold voltage different than the first threshold voltage and is adjusted to provide a second drive strength different than the first drive strength, where the transconductance circuit has a linearity that is optimized based on the first and second drive strengths. The transconductance circuit can further include a third programmable pull-down switch coupled in parallel with the first programmable pull-down switch and having a gate terminal configured to receive the input signal, where the third programmable pull-down switch has a third threshold voltage different than the first and second threshold voltages and is adjusted to provide a third drive strength different than the first drive strength to optimize the linearity of the transconductance circuit.

The transconductance circuit can further include a programmable current source having a first terminal coupled to the source terminals of the first and second programmable pull-down switches and having a second terminal coupled to a ground line, where the programmable current source is activated during a first gain mode and is deactivated during a second gain mode. The transconductance circuit can further include a programmable source degeneration resistor directly coupled to the source terminals of the first and second programmable pull-down switches, where the programmable source degeneration resistor is adjusted to provide a first resistance during the first gain mode and to provide a second resistance, less than the first resistance, during the second gain mode.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having one or more transceivers in accordance with some embodiments.

FIG. 3 is a diagram of an illustrative continuous-time filter circuit in accordance with some embodiments.

FIG. 4 is a diagram of an illustrative discrete-time filter circuit in accordance with some embodiments.

FIG. 5 is a circuit diagram of an illustrative transconductance circuit in accordance with some embodiments.

FIG. 6 is a diagram showing at least two different operating modes for a transconductance circuit of the type shown in at least FIGS. 3-5 in accordance with some embodiments.

FIG. 7 is a plot of transconductance (Gm) as a function of input voltage (Vin) for various transconductance circuits with different transistor threshold voltages in accordance with some embodiments.

FIG. 8 is a plot of third-order transconductance (Gm3) as a function of transistor gate-to-source voltage (Vgs) for transconductance circuits with various combinations of transistor threshold voltages of equal weighting in accordance with some embodiments.

FIG. 9 is a plot of third-order transconductance (Gm3) as a function of transistor gate-to-source voltage (Vgs) for transconductance circuits with various combinations of transistor threshold voltages of different weightings in accordance with some embodiments.

FIG. 10 is a circuit diagram of an adjustable pull-up switch in accordance with some embodiments.

FIG. 11 is a circuit diagram of an adjustable pull-down switch in accordance with some embodiments.

### DETAILED DESCRIPTION

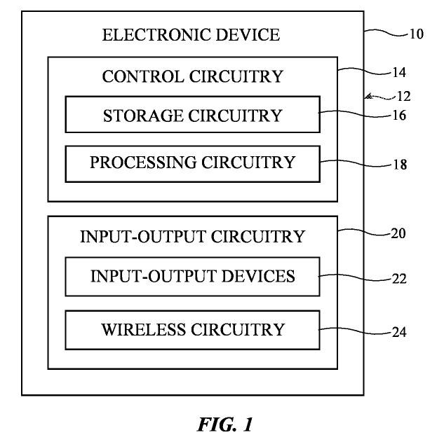

An electronic device such as device 10 of FIG. 1 may be provided with wireless circuitry. Wireless circuitry can include a receiver configured to merge multiple receive (RX) chains. Such receiver can include a baseband filter with high linearity requirements. The baseband filter can be a continuous-time filter or a discrete-time filter. The baseband filter can include a transconductance circuit configured to serve as an input stage for the filter. The overall linearity of the baseband filter is dominated by the linearity of the input transconductance circuit.

In accordance with an embodiment, the transconductance circuit can include multiple pull-down switches and multiple pull-up switches coupled between programmable current sources and programmable source degeneration resistors. The pull-down switches can include n-type transistors having different threshold voltage levels. The pull-up switches can include p-type transistors having different threshold voltage levels. The pull-up and pull-down transistors can have adjustable drive strengths. The pull-up transistors, pull-down transistors, programmable current sources, and programmable source degeneration transistors can be selectively tuned (adjusted) depending on whether the transconductance circuit is being operated in a low gain mode or a high gain mode. A baseband filter configured and operated in this way is technically advantageous and beneficial to provide improved linearity and noise figure across different gain modes and over PVT (process, voltage, temperature) variations.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user’s head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols – sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support or perform radio-frequency signal transmission and/or reception for device 10. Wireless circuitry 24 may be used for wireless communications. Wireless communications performed by wireless circuitry 24 may include or involve wireless data communications (e.g., where wireless data is carried by radio-frequency signals conveyed between wireless circuitry 24 and other communications equipment bidirectionally or unidirectionally), radio-frequency signal transmission, radio-frequency signal reception, and/or radio-based spatial ranging/sensing (e.g., radio detection and ranging (radar) operations, shorter range object detection such as near-field radio-frequency signal-based object detection, etc.). Radio-frequency signals conveyed by wireless circuitry 24 may include or carry wireless data (e.g., organized into frames, packets, symbols, datagrams, etc.), radar or other spatial ranging waveforms, continuous wave signals, chirp signals, control signals, management signals, reference signals, beacon signals, tones, pulses/impulses, waveforms associated with one or more communications protocols, and/or any other radio-frequency waveforms or signals.

Wireless circuitry 24 is thus sometimes also referred to herein as wireless communications circuitry 24, wireless communication circuitry 24, communications circuitry 24, or simply as circuitry 24. Wireless circuitry 24 may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s). Some or all of the components of wireless circuitry 24 may be disposed on, mounted to, communicatively coupled to, and/or integrated within the same substrate (e.g., a printed circuit board, semiconductor substrate, chip, integrated circuit (IC), IC packages, etc.) or may be distributed between two or more substrates (e.g., printed circuit boards, semiconductor substrates, chips, ICs, IC packages, etc.).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), 6G bands between 100-1000 GHz (e.g., sub-THz, THz, tremendously high frequency or THF bands, etc.), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

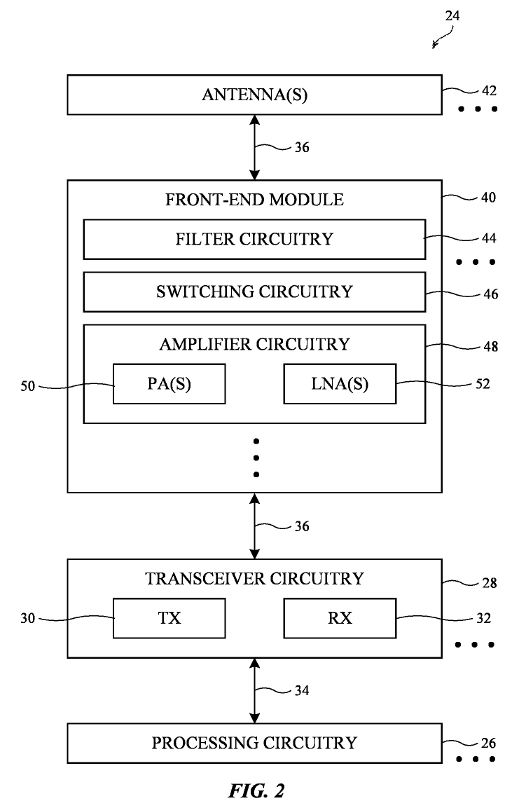

FIG. 2 is a diagram showing illustrative components within wireless circuitry 24. As shown in FIG. 2, wireless circuitry 24 may include processing circuitry such as processing circuitry 26, radio-frequency (RF) transceiver circuitry such as radio-frequency transceiver 28, radio-frequency front-end circuitry such as radio-frequency front-end module (FEM) 40, and antenna(s) 42. Processing circuitry 26 may be a baseband processor, application processor, general purpose processor, microprocessor, microcontroller, digital signal processor, host processor, application specific signal processing hardware, or other type of processor. Processing circuitry 26 may be coupled to transceiver 28 over path 34. Transceiver 28 may be coupled to antenna 42 via radio-frequency transmission line path 36. Radio-frequency front-end module 40 may be disposed on radio-frequency transmission line path 36 between transceiver 28 and antenna 42.

In the example of FIG. 2, wireless circuitry 24 is illustrated as including only a single processing unit 26, a single transceiver 28, a single front-end module 40, and a single antenna 42 for the sake of clarity. In general, wireless circuitry 24 may include any desired number of processing units 26, any desired number of transceivers 28, any desired number of front-end modules 40, and any desired number of antennas 42. Each processing unit 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front-end modules 40 may be disposed on the same radio-frequency transmission line path 36. If desired, one or more of the radio-frequency transmission line paths 36 in wireless circuitry 24 may be implemented without any front-end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processing circuitry 26 may provide transmit signals (e.g., digital or baseband signals) to transceiver 28 over path 34. Transceiver 28 may further include circuitry for converting the transmit (baseband) signals received from processing circuitry 26 into corresponding radio-frequency signals. For example, transceiver circuitry 28 may include mixer circuitry for up-converting (or modulating) the transmit (baseband) signals to radio frequencies prior to transmission over antenna 42. The example of FIG. 2 in which processing circuitry 26 communicates with transceiver 28 is merely illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front-end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front-end module 40. Transceiver 28 may include circuitry such as receiver (RX) 32 for receiving signals from front-end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processing circuitry 26 over path 34.

Front-end module (FEM) 40 may include radio-frequency front-end circuitry that operates on the radio-frequency signals conveyed (transmitted and/or received) over radio-frequency transmission line path 36. FEM 40 may, for example, include front-end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front-end module components may be mounted to a common (shared) substrate such as a rigid printed circuit board substrate or flexible printed circuit substrate. If desired, the various front-end module components may also be integrated into a single integrated circuit chip. If desired, amplifier circuitry 48 and/or other components in front-end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front-end module 40. For example, transceiver 28 may be formed on another substrate such as the main logic board of device 10, a rigid printed circuit board, or flexible printed circuit that is not a part of front-end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processing circuitry 26 and/or portions of transceiver 28 (e.g., a host processor on transceiver 28) may form a part of control circuitry 14. Control circuitry 14 (e.g., portions of control circuitry 14 formed on processing circuitry 26, portions of control circuitry 14 formed on transceiver 28, and/or portions of control circuitry 14 that are separate from wireless circuitry 24) may provide control signals (e.g., over one or more control paths in device 10) that control the operation of front-end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

Certain transceiver architectures can include multiple receiver paths. Conventional receiver topologies that include multiple receiver paths include a narrowband filter in each of the multiple receiver paths. Having one narrowband filter in each receiver path can consume a substantial amount of circuit area, especially when the number of receiver paths is large. Having a single wideband filter configured to merge the multiple receiver paths can help substantially reduce power consumption while minimizing the area overhead. It can be challenging to design such wideband filter that satisfies the noise and linearity performance criteria across a broad range of operating conditions.

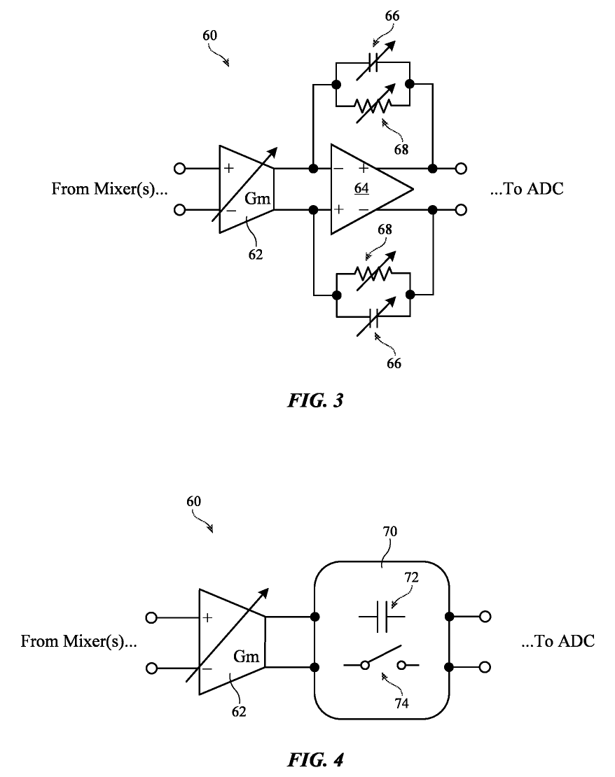

In accordance with an embodiment, a receiver that includes a filter such as filter circuit 60 of FIG. 3 is provided. Filter circuit 60 can have an input coupled to one or more mixers or other filters and an output coupled to a data converter such as an analog-to-digital converter (ADC) or other filters. The one or more mixers can output corresponding downconverted (demodulated) baseband signals to the input of filter 60. The multiple mixers at the input of filter circuit 60 can be part of different receive paths of wireless circuitry 24. Such type of filter circuit 60 configured to receive baseband signals from multiple receiver paths can be a wideband baseband filter. Receiver 32 (see FIG. 2) that includes such wideband baseband filter 60 is thus a wideband receiver.

As shown in FIG. 3, baseband filter circuit 60 can include an input stage and an output stage. The input stage of filter circuit 60 may be a programmable transconductance circuit 62, whereas the output stage of filter circuit 60 may be a transimpedance amplifier 64 with one or more feedback components. A “transconductance” circuit can refer to and be defined herein as an electronic circuit configured to convert an input voltage to an output current. Transimpedance amplifier 64 can have a differential input coupled to the output of transconductance circuit 62 and a differential output coupled to a succeeding ADC. Programmable feedback capacitors 66 and/or programmable feedback resistors 68 can be coupled between the differential output and the differential input of transimpedance amplifier 64. Filter circuit 60 of the type shown in FIG. 3 represents a continuous-time filter circuit.

The example of FIG. 3 in which filter circuit 60 is implemented as a continuous-time filter is illustrative. FIG. 4 is a diagram showing another implementation of filter circuit 60. As shown in FIG. 4, the input stage of filter circuit 60 may be a programmable transconductance circuit 62, but the output stage of filter circuit 60 may be switched capacitor circuit 70. Switched capacitor circuit 70 can have a differential input coupled to the output of transconductance circuit 62 and a differential output coupled to a succeeding ADC. Switched capacitor circuit 70 can generally include one or more capacitors 72 coupled to one or more associated switches 74. One of the switches 74 can be selectively activated to switch a respective one of the capacitors 74 into use, or vice versa. Filter circuit 60 of the type shown in FIG. 4 represents a discrete-time filter circuit. The example of FIG. 4 in which filter circuit 60 is a discrete-time filter and the example of FIG. 3 in which filter circuit 60 is a continuous-time filter are illustrative and not intended to limit the scope of the present embodiments. If desired, other ways of implementing filter circuit 60 can be implemented.

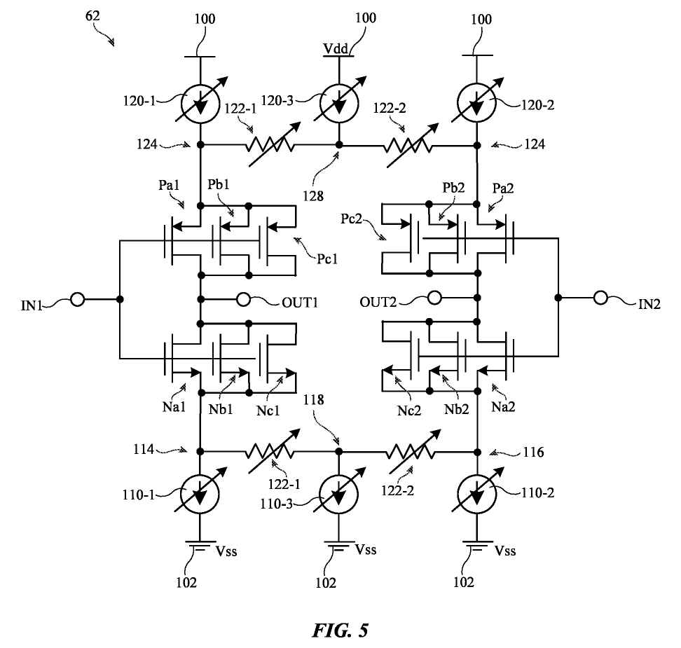

In general, the overall linearity and noise performance of filter circuit 60 can be dominated by the linearity and noise characteristics of the input transconductance circuit 62. FIG. 5 is a circuit diagram of an illustrative transconductance circuit 62 in accordance with some embodiments. Transconductance circuit 62 has a symmetrical structure (e.g., the structure of the left half is identical to the structure of the right half). As shown in FIG. 5, transconductance circuit 62 can include multiple pull-down switches, multiple pull-up switches, multiple programmable current sources, and multiple programmable resistors. A “pull-down” switch or transistor can refer to and be defined herein as a device configured to pull a node driven by that switch down towards a ground voltage. The pull-down switches can include pull-down transistors Na1, Na2, Nb1, Nb2, Nc1, and Nc2, which can be implemented as n-type metal-oxide-semiconductor (NMOS) transistors, as an example. A “pull-up” switch or transistor can refer to and be defined herein as a device configured to pull a node driven by that switch up towards a positive power supply voltage Vdd. The pull-up switches can include pull-up transistors Pa1, Pa2, Pb1, Pb2, Pc1, and Pc2, which can be implemented as p-type metal-oxide semiconductor (PMOS) transistors, as an example. The various pull-up switches and pull-down transistors all have gates coupled to input terminals IN1 and IN2 and can all be referred to as “input” transistors. The example of FIG. 5 in which the transistors of transconductance circuit 62 are implemented as MOS transistors is exemplary. In general, the pull-down and pull-up switches of transconductance circuit 62 can be implemented using metal-oxide-semiconductor field-effect transistors (MOSFETs), bipolar junction transistors (BJTs), insulated-gate bipolar transistors (IGBTs), junction field-effect transistors (JFETs), tunnel field-effect transistors (TFETs), fin field-effect transistors (FinFETs), silicon-on-insulator (SOI) transistors, carbon nanotube transistors, nanowire transistors, a combination of these transistors, and/or other types of transistors.

Transistor Na1 can have a gate terminal coupled to a first input terminal IN1 of circuit 62, a drain terminal coupled to a first output terminal OUT1 of circuit 62, and a source terminal coupled to a differential tail node 114. The terms “source” and “drain” are sometimes used interchangeably when referring to current-conducting terminals of a metal-oxide-semiconductor transistor. The source and drain terminals are therefore sometimes referred to as “source-drain” terminals (e.g., a transistor has a gate terminal, a first source-drain terminal, and a second source-drain terminal). Furthermore, the term “activate” with respect to a switch (or transistor) may refer to or be defined herein as an action that places the switch in an “on”or low-impedance state such that the two terminals of the switch are electrically connected to conduct current. Activating a switch can sometimes be referred to as turning on or closing a switch. The term “deactivate” with respect to a switch (or transistor) may refer to or be defined herein as an action that places the switch in an “off” or high-impedance state such that the two terminals of the switch/transistor are electrically disconnected with minimal leakage current. Deactivating a switch can sometimes be referred to as turning off or opening a switch.

Transistor Nb1 can have a gate terminal coupled to the first input terminal IN1, a drain terminal coupled to the first output terminal OUT1, and a source terminal coupled to differential tail node 114. Arranged in this way, transistor Nb1 can be considered to be coupled “in parallel” with transistor Na1. Similarly, transistor Nc1 can have a gate terminal coupled to the first input terminal IN1, a drain terminal coupled to the first output terminal OUT1, and a source terminal coupled to differential tail node 114. Arranged in this way, transistor Nc1 can be considered to be coupled “in parallel” with transistors Na1 and Nb1. The terminology “in parallel” can refer to and be defined herein as a connection where the source-drain terminals of two transistors are shorted to each other (i.e., the source terminals of two transistors are shorted, and the drain terminals of the two transistors are shorted).

At the other input, transistor Na2 can have a gate terminal coupled to a second input terminal IN2 of circuit 62, a drain terminal coupled to a second output terminal OUT2 of circuit 62, and a source terminal coupled to a differential tail node 116. Input terminals IN1 and IN2 can serve as a differential input port of transconductance circuit 62 (e.g., input terminal IN1 can receive a first input signal, whereas input terminal IN2 can receive a second input signal that is inverted with respect to the first input signal; the first and second input signals can collectively form a differential input signal). Output terminals OUT1 and OUT2 can serve as a differential output port of transconductance circuit 62. Transistor Nb2 can have a gate terminal coupled to the second input terminal IN2, a drain terminal coupled to the second output terminal OUT2, and a source terminal coupled to differential tail node 116. Arranged in this way, transistor Nb2 can be considered to be coupled “in parallel” with transistor Na2. Similarly, transistor Nc2 can have a gate terminal coupled to the second input terminal IN2, a drain terminal coupled to the second output terminal OUT2, and a source terminal coupled to differential tail node 116. Arranged in this way, transistor Nc2 can be considered to be coupled “in parallel” with transistors Na2 and Nb2.

The programmable current sources can include programmable current sources 110-1, 110-2, 110-3, 120-1, 120-2, and 120-3. These programmable current sources may be digitally controlled using a number of bits. For example, programmable current source 110-1 may be controlled by a 3-bit signal. When this 3-bit signal is “000”, then current source 110-1 can be deactivated (e.g., completely turned off to pass no current). When this 3-bit signal is “111”, then current source 110-1 can be fully activated (e.g., completely turned on to pass a maximum amount of current). When this 3-bit signal has some intermediate value such as “100”, then current source 110-1 can be partially activated, a portion of which is turned on to pass some intermediate amount of current that is less than the maximum amount of current. Programmable current sources 110-2, 110-3, 120-1, 120-2, and 120-3 can each be digitally controlled using respective control bits. This example in which the programmable current sources are controlled using 3-bit signals is illustrative. In general, the programmable can be controlled using any number of bits. Programmable current source 110-1 has a first terminal coupled to differential tail node 114 and a second terminal coupled to a ground power supply line 102 (e.g., a ground line on which a ground voltage Vss is provided). Programmable current source 110-2 has a first terminal coupled to differential tail node 116 and second terminal coupled to ground power supply line 102. Current sources 110-1 and 110-2 coupled to differential tail nodes 114 and 116, respectively, can be referred to as “differential mode” current sources.

The programmable resistors can include programmable resistors 112-1, 112-2, 122-1, and 122-2. These programmable resistors can have tunable (adjustable) resistances. Programmable resistor 112-1 may have a first terminal coupled to differential tail node 114 and a second terminal coupled to a common tail node 118. Programmable resistor 112-2 may have a first terminal coupled to differential tail node 116 and a second terminal coupled to the common tail node 118. Resistors 112-1 and 112-2 that are connected to the source terminals of the pull-down transistors can sometimes be referred to as source “degeneration” resistors. The use of source degeneration resistors for the pull-down transistors can be technically advantageous to help improve the linearity of transconductance circuit 62. Programmable current source 110-3 has a first terminal coupled to common tail node 118 and second terminal coupled to ground power supply line 102. Current source 110-3 coupled to common tail node 118 that is interposed between differential tail nodes 114 and 116 can be referred to as a “common mode” current source.

At the pull-up side, transistor Pa1 can have a gate terminal coupled to first input terminal IN1, a drain terminal coupled to first output terminal OUT1, and a source terminal coupled to a differential tail node 124. Transistor Pb1 can have a gate terminal coupled to the first input terminal IN1, a drain terminal coupled to the first output terminal OUT1, and a source terminal coupled to differential tail node 124. Arranged in this way, transistor Pb1 can be considered to be coupled “in parallel” with transistor Pa1. Similarly, transistor Pc1 can have a gate terminal coupled to the first input terminal IN1, a drain terminal coupled to the first output terminal OUT1, and a source terminal coupled to differential tail node 124. Arranged in this way, transistor Pc1 can be considered to be coupled “in parallel” with transistors Pa1 and Pb1.

At the other input, transistor Pa2 can have a gate terminal coupled to second input terminal IN2, a drain terminal coupled to second output terminal OUT2, and a source terminal coupled to a differential tail node 126. Transistor Pb2 can have a gate terminal coupled to the second input terminal IN2, a drain terminal coupled to the second output terminal OUT2, and a source terminal also coupled to differential tail node 126. Arranged in this way, transistor Pb2 can be considered to be coupled “in parallel” with transistor Pa2. Similarly, transistor Pc2 can have a gate terminal coupled to the second input terminal IN2, a drain terminal coupled to the second output terminal OUT2, and a source terminal also coupled to differential tail node 126. Arranged in this way, transistor Pc2 can be considered to be coupled “in parallel” with transistors Pa2 and Pb2.

Programmable current source 120-1 has a first terminal coupled to differential tail node 124 and a second terminal coupled to a positive power supply line 100 (e.g., a positive power supply terminal on which a positive power supply voltage Vdd is provided). Programmable current source 120-2 has a first terminal coupled to differential tail node 126 and second terminal coupled to positive power supply line 100. Current sources 120-1 and 120-2 coupled to differential tail nodes 124 and 126, respectively, can be referred to as “differential mode” current sources.

Programmable resistor 122-1 may have a first terminal coupled to differential tail node 124 and a second terminal coupled to a common tail node 128. Programmable resistor 122-2 may have a first terminal coupled to differential tail node 126 and a second terminal coupled to the common tail node 128. Resistors 122-1 and 122-2 that are connected to the source terminals of the pull-up transistors can sometimes also be referred to as source “degeneration” resistors. The use of source degeneration resistors for the pull-up transistors can be technically advantageous to help improve the linearity of transconductance circuit 62. Programmable current source 120-3 has a first terminal coupled to common tail node 128 and second terminal coupled to positive power supply line 100. Current source 120-3 coupled to common tail node 128 that is interposed between differential tail nodes 124 and 126 can be referred to as a “common mode” current source.

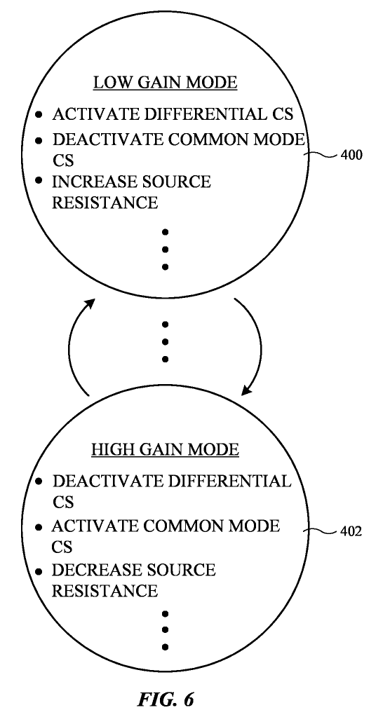

Transconductance circuit 62 of the type described in connection with FIG. 5 can be configured to operate in multiple different gain modes. FIG. 6 is a diagram showing at least two different gain modes that transconductance circuit 62 can be operated. As shown in FIG. 6, transconductance circuit 62 can be configured to operate in a first (low) gain mode 400 and a second (high) gain mode 402. Low gain mode 400 can be employed when the input signal swing is relatively large (e.g., the amount of signal gain needed is relatively small). During the low gain mode, the differential mode current sources can be fully activated (e.g., current sources 110-1, 110-2, 120-1, and 120-2 are all switched into use using all “1” control bits), whereas the common mode current sources are deactivated (e.g., current sources 110-3 and 120-3 are switched out of use or completely turned off using all “0” control bits). During the low gain mode, the source degeneration resistors 112-1, 112-2, 122-1, and 122-2 can all be adjusted to increase their resistance values relative to the high gain mode. The resistance values of resistors 112-1 and 112-2 should be the same as each other. The resistance values of resistors 122-1 and 122-2 should also be the same as each other. Increasing the resistance values of the source degeneration resistors while the common mode current sources are deactivated will not impact the voltage headroom of transconductance circuit 62. The use of source degeneration resistors for the pull-down and pull-up transistors can be technically advantageous to help improve the linearity of transconductance circuit 62. Configured and operated in this way, the linearity performance of circuit 62 can be optimized in the low gain mode.

In contrast, high gain mode 402 can be employed when the input signal swing is relatively small (e.g., the input signal needs to be amplified using a larger gain). During the high gain mode, the differential mode current sources can be deactivated (e.g., current sources 110-1, 110-2, 120-1, and 120-2 are all switched out of use or turned off using all “0” bits), whereas the common mode current sources are fully activated (e.g., current sources 110-3 and 120-3 are switched into use or turned on using all “1” bits). During the high gain mode, the source degeneration resistors 112-1, 112-2, 122-1, and 122-2 can all be adjusted to decrease their resistance values relative to the low gain mode, to help improve the voltage headroom for circuit 62. The resistance values of resistors 112-1 and 112-2 should be the same as each other. The resistance values of resistors 122-1 and 122-2 should also be the same as each other. Configured and operated in this way, the noise performance of circuit 62 can be optimized in the low gain mode while providing sufficient voltage headroom for signals produced across the differential output of transconductance circuit 62.

The example of FIG. 6 showing how transconductance circuit 62 is operable in a low gain mode and a high gain mode is illustrative. In general, transconductance circuit 62 can be configured to operate in two or more gain modes, three or more different gain modes, four or more different gain modes, five to ten different gain modes, or more than ten different gain modes. The states of the programmable current sources and the source degeneration transistors can be adjusted accordingly depending on the needs of each gain mode. For example, in an intermediate gain mode offering a gain greater than the low gain mode but less than the high gain mode, at least some of the programmable current sources can be partially activated (e.g., by using digital control bits having both “0” and “1”). In the intermediate gain mode, the resistance values of the source degeneration resistors should be adjusted to be less than their resistance in the low gain mode and greater than their resistance in the high gain mode.

As described above in connection with FIGS. 3 and 4, the overall linearity of baseband filter 60 predominately depends on the linearity of transconductance circuit 62. The linearity of a transconductance circuit is a function of its transconductance. A circuit’s transconductance or “Gm” can be defined as a ratio of the change in output current to the change in input voltage. Conventional transconductance circuits typically exhibit a transconductance Gm that varies significantly over PVT (process, voltage, temperature) variations. Such variation in transconductance Gm of a transconductance circuit can degrade the overall linearity of the baseband filter.

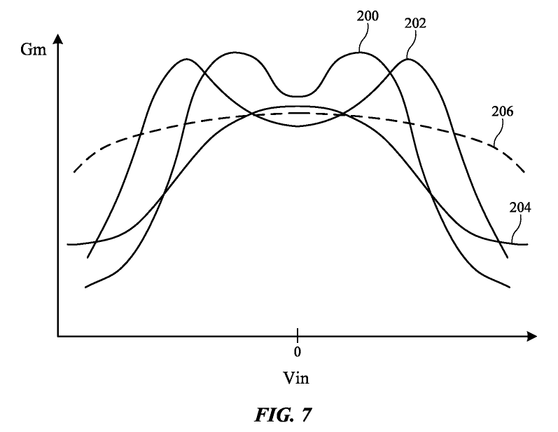

In accordance with some embodiments, transconductance circuit 62 can be provided with transistors having different threshold voltages. Transistors of different threshold voltages can exhibit different Gm profiles. FIG. 7 is a plot of transconductance Gm as a function of input voltage Vin of transconductance circuit 62. Curve 200 may represent a first transconductance profile associated with circuit 62 having pull-up and pull-down transistors all implemented using a first threshold voltage. Curve 202 may represent a second transconductance profile associated with circuit 62 having pull-up and pull-down transistors all implemented using a second threshold voltage different than the first threshold voltage. Curve 204 may represent a third transconductance profile associated with circuit 62 having pull-up and pull-down transistors all implemented using a third threshold voltage different than the first and second threshold voltages.

As an example, the first threshold voltage may be greater than the second threshold voltage, and the second threshold voltage may be greater than the third threshold voltage. For instance, transistors having the first threshold voltage can be referred to as “standard threshold voltage” (SVT) devices; transistors having the second threshold voltage can be referred to as “low threshold voltage” (LVT) devices; and transistors having the third threshold voltage can be referred to as “ultra-low threshold voltage” (ULVT) devices. As another example, transistors having the first threshold voltage can be referred to as “high threshold voltage” (HVT) devices; transistors having the second threshold voltage can be referred to as SVT devices; and transistors having the third threshold voltage can be referred to as LVT devices.

As shown in FIG. 7, each of curves 200, 202 and 204 exhibits significant variation across the input voltage range. In contrast, curve 206 represents a transconductance profile associated with circuit 62 having pull-up and pull-down transistors of different threshold voltages. Referring to FIG. 5, a first portion of the transistors (e.g., transistors Na1, Na2, Pa1, and Pa2) can have the first threshold voltage; a second portion of the transistors (e.g., transistors Nb1, Nb2, Pb1, and Pb2) can have the second threshold voltage; and a third portion of the transistors (e.g., transistors Nc1, Nc2, Pc1, and Pc2) can have the third threshold voltage. Referring back to FIG. 7, curve 206 is relatively flat, compared to curves 200, 202, and 204, across the range of input voltages. In other words, using transistors of different threshold voltages (e.g., a combination of SVT transistors, LVT transistors, and ULVT transistors) within transconductance circuit 62 can be technically advantageous and beneficial to provide a more stable and robust Gm over PVT variations.

Another metric of quantifying the linearity of transconductance circuit 62 is its third order transconductance or “Gm3.” Gm3 is a third order derivative of transconductance Gm. Third order non-linearity Gm3 can, if not properly mitigated, can cause gain compression and third order intermodulation distortion, as examples.

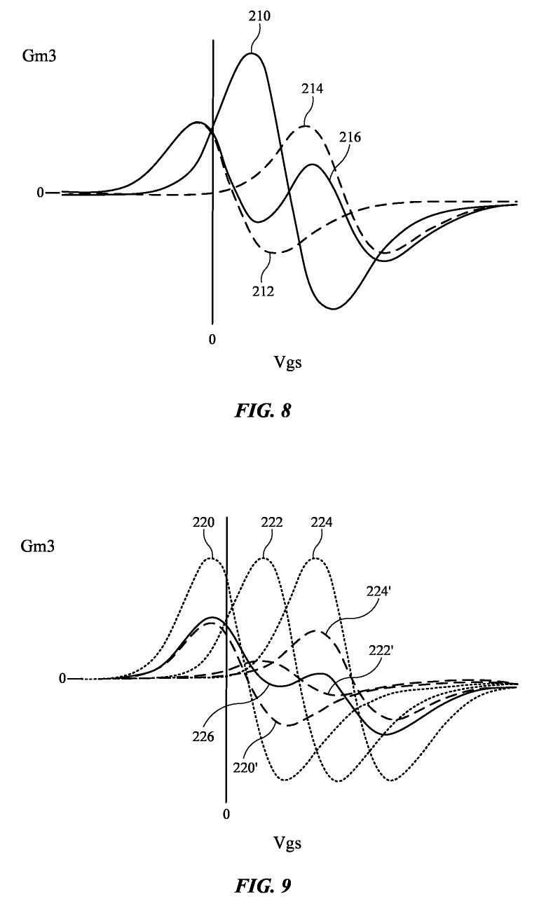

FIG. 8 is a plot of 3^{rd} order transconductance Gm3 as a function of gate-to-source voltage Vgs of the pull-up or pull-down transistors. Curve 210 may represent the Gm3 profile of a conventional transconductance circuit including transistors all having the same threshold voltage (e.g., all LVT transistors). Curve 212 may represent the Gm3 profile of a transconductance circuit having all SVT transistors. Curve 214 may represent the Gm3 profile of a transconductance circuit having all ULVT transistors. Curve 216 may represent the Gm3 profile of a transconductance circuit 62, where half of the pull-down and pull-up transistors (e.g., transistors Na1, Na2, Pa1, and Pa2) are SVT transistors, and where the other half of the pull-down and pull-up transistors (e.g., transistors Nb1, Nb2, Pb1, and Pb2) are ULVT transistors. In such an arrangement, transistors Nc1, Nc2, Pc1, and Pc2 can be omitted from transconductance circuit 62. As shown in FIG. 8, curve 216 provides a much flatter Gm3 profile compared to curve 210. Thus, using transistors of different threshold voltages can provide improved linearity over conventional topologies that employ transistors all with the same threshold voltage.

FIG. 9 shows another plot of Gm3 as a function of gate-to-source voltage Vgs of the pull-up or pull-down transistors. Curve 220 may represent the Gm3 profile of a transconductance circuit having all ULVT transistors. Curve 222 may represent the Gm3 profile of a transconductance circuit having all LVT transistors. Curve 224 may represent the Gm3 profile of a transconductance circuit having all SVT transistors. Dotted curve 220’ may represent the Gm3 profile if the ULVT transistors are sized relatively smaller than those associated with curve 220. Dotted curve 222’ may represent the Gm3 profile if the LVT transistors are sized relatively smaller than those associated with curve 222. Dotted curve 224’ may represent the Gm3 profile if the SVT transistors are sized relatively smaller than those associated with curve 224.

Curve 226 may represent the Gm3 profile of a transconductance circuit 62, where a first portion of the pull-down and pull-up transistors (e.g., transistors Na1, Na2, Pa1, and Pa2) are ULVT transistors, a second portion of the pull-down and pull-up transistors (e.g., transistors Nb1, Nb2, Pb1, and Pb2) are LVT transistors, and a third portion of the pull-down and pull-up transistors (e.g., transistors Nc1, Nc2, Pc1, and Pc2) are SVT transistors. As shown in FIG. 9, curve 226 provides a much flatter Gm3 profile compared to any of the other curves over a wide range of Vgs. In accordance with some embodiments, the weighting of transistors of different threshold voltages can be adjusted to optimize for a flatter Gm3 profile. As an example, it can be determined that using 40% SVT transistors, 45% ULVT transistors, and 15% LVT transistors can produce the flattest Gm3 profile. As another example, it can be determined that using 30% SVT transistors, 20% ULVT transistors, and 50% LVT transistors can produce the flattest Gm3 profile. These percentage weightings refer to the relative sizing of the parallel transistors and are merely illustrative. Thus, having different weightings among, say, pull-down transistors Na1, Nb1, and Nc1 can help further enhance the linearity of transconductance circuit 62. The relative weightings of pull-down transistor Na1, Nb1, and Nc1 can be respectively applied to pull-down transistors Na2, Nb2, and Nc2, to pull-up transistors Pa1, Pb1, and Pc1, and also to pull-up transistors Pa2, Pb2, and Pc2.

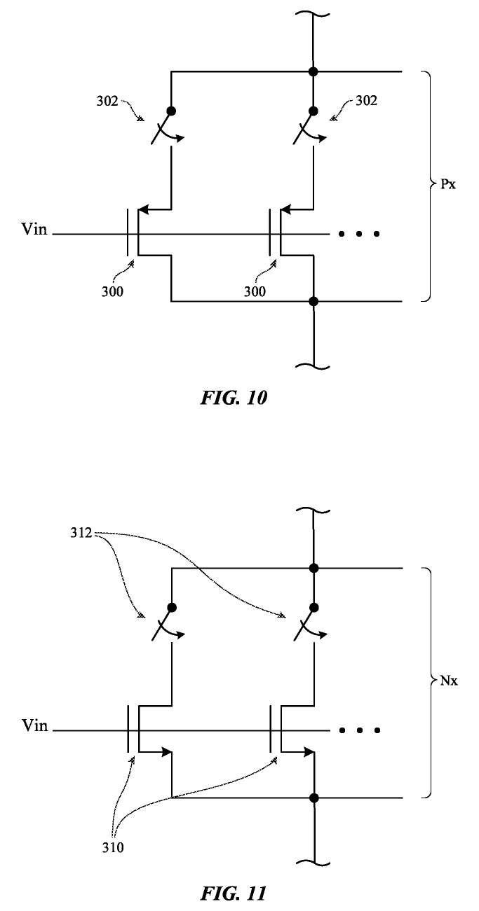

The relative weighting of the pull-down and pull-up transistors can be adjusted by adjusting the width or drive-ability of each transistor shown in FIG. 5. Although each transistor of FIG. 5 is shown as a single discrete transistor, each pull-up transistor of FIG. 5 can optionally be implemented as an adjustable (programmable) pull-up switch Px as illustrated FIG. 10. Pull-up switch Px can represent any one of pull-up transistors Pa1, Pb1, Pc1, Pa2, Pb2, and Pc2 in FIG. 5. FIG. 10 shows how pull-up switch Px can include an array of p-type transistors 300 that are selectively activated by respective switches 302. A larger number of switches 302 can be activated to increase the overall drive strength, and thus effective width or relative percentage weighting, of switch Px. A smaller number of switches 302 can be activated to decrease the overall drive strength, and thus effective width or relative percentage weighting, of switch Px. Switch Px implemented in this way is sometimes referred to as a programmable pull-up transistor or switch.

Similarly, each pull-down transistor of FIG. 5 can optionally be implemented as an adjustable (programmable) pull-down switch Nx as illustrated FIG. 11. Pull-down switch Nx can represent any one of pull-down transistors Na1, Nb1, Nc1, Na2, Nb2, and Nc2 in FIG. 5. FIG. 11 shows how pull-down switch Nx can include an array of n-type transistors 310 that are selectively activated by respective switches 312. A larger number of switches 312 can be activated to increase the overall drive strength, and thus effective width or relative percentage weighting, of switch Nx. A smaller number of switches 312 can be activated to decrease the overall drive strength, and thus effective width or relative percentage weighting, of switch Nx. Switch Nx implemented in this way is sometimes referred to as a programmable pull-down transistor or switch.

The methods and operations described above in connection with FIGS. 1-11 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. A wireless receiver comprising:
a plurality of receive paths; and
a filter circuit configured to receive signals from the plurality of receive paths, wherein the filter circuit includes a transconductance circuit that comprises
a first pull-down transistor having a first threshold voltage, and
a second pull-down transistor coupled in parallel with the first pull-down transistor and having a second threshold voltage different than the first threshold voltage.

2. The wireless receiver of claim 1, wherein the filter circuit further comprises:
a transimpedance amplifier having an input coupled to the transconductance circuit; and
programmable resistors and capacitors coupled across the input and an output of the transconductance circuit.

3. The wireless receiver of claim 1, wherein the filter circuit further comprises:
a switched capacitor circuit having an input coupled to the transconductance circuit and having an output coupled to an analog-to-digital converter.

4. The wireless receiver of claim 1, wherein the transconductance circuit further comprises:
a third pull-down transistor coupled in parallel with the first and second pull-down transistors and having a third threshold voltage different than the first and second threshold voltages, wherein the first, second, and third pull-down transistors have gate terminals coupled to a first input terminal of the transconductance circuit.

5. The wireless receiver of claim 4, wherein the transconductance circuit further comprises:
a fourth pull-down transistor having the first threshold voltage;
a fifth pull-down transistor coupled in parallel with the fourth pull-down transistor and having the second threshold voltage; and
a sixth pull-down transistor coupled in parallel with the fourth and fifth pull-down transistors and having the third threshold voltage, wherein the fourth, fifth, and sixth pull-down transistors have gate terminals coupled to a second input terminal, different than the first input terminal, of the transconductance circuit.

6. The wireless receiver of claim 5, wherein the transconductance circuit further comprises:
a first programmable current source coupled to source terminals of the first, second, and third pull-down transistors; and
a second programmable current source coupled to source terminals of the fourth, fifth, and sixth pull-down transistors.

7. The wireless receiver of claim 6, wherein the transconductance circuit further comprises:
a first programmable resistor having a first terminal coupled to the first programmable current source and having a second terminal coupled to a node;
a second programmable resistor having a first terminal coupled to the second programmable current source and having a second terminal coupled to the node; and
a third programmable current source coupled to the node.

8. The wireless receiver of claim 7, wherein:
during a first gain mode, the first and second programmable current sources are fully activated and the third programmable current source is deactivated;
during a second gain mode, the first and second programmable current sources are deactivated and the third programmable current source is fully activated; and
during a third gain mode, at least some of the first and second programmable current sources are partially activated.

9. The wireless receiver of claim 8, wherein:
during the first gain mode, the first and second programmable resistors are adjusted to a first resistance value; and
during the second gain mode, the first and second programmable resistors are adjusted to a second resistance value less than the first resistance value.

10. The wireless receiver of claim 5, wherein the transconductance circuit further comprises:
a first pull-up transistor coupled in series with the first pull-down transistor;
a second pull-up transistor coupled in parallel with the first pull-up transistor; and
a third pull-up transistor coupled in parallel with the first and second pull-up transistors, wherein the first, second, and third pull-up transistors have gate terminals coupled to the first input terminal of the transconductance circuit.

11. A transconductance circuit comprising:
a first pull-up transistor having a source terminal, a drain terminal that is coupled to a first output terminal, and a gate terminal that is configured to receive an input signal, wherein the first pull-up transistor has a first threshold voltage;
a second pull-up transistor having a source terminal shorted to the source terminal of the first pull-up transistor, a drain terminal shorted to the drain terminal of the first pull-up transistor, and a gate terminal that is configured to receive the input signal, wherein the second pull-up transistor has a second threshold voltage different than the first threshold voltage; and
a first programmable current source having a first terminal coupled to the source terminals of the first and second pull-up transistors and having a second terminal coupled to a positive power supply line.

12. The transconductance circuit of claim 11, further comprising:
a third pull-up transistor having a source terminal shorted to the source terminal of the first pull-up transistor, a drain terminal shorted to the drain terminal of the first pull-up transistor, and a gate terminal that is configured to receive the input signal, wherein the third pull-up transistor has a third threshold voltage different than the first and second threshold voltages.

13. The transconductance circuit of claim 12, further comprising:
a fourth pull-up transistor having a source terminal, a drain terminal that is coupled to a second output terminal, and a gate terminal that is configured to receive an additional input signal that is inverted with respect to the input signal, wherein the fourth pull-up transistor has the first threshold voltage;
a fifth pull-up transistor having a source terminal shorted to the source terminal of the fourth pull-up transistor, a drain terminal shorted to the drain terminal of the fourth pull-up transistor, and a gate terminal that is configured to receive the additional input signal, wherein the fifth pull-up transistor has the second threshold voltage; and
a sixth pull-up transistor having a source terminal shorted to the source terminal of the fourth pull-up transistor, a drain terminal shorted to the drain terminal of the fourth pull-up transistor, and a gate terminal that is configured to receive the additional input signal, wherein the sixth pull-up transistor has the third threshold voltage.

14. The transconductance circuit of claim 13, further comprising:
a second programmable current source having a first terminal coupled to the source terminals of the fourth, fifth, and sixth pull-up transistors and having a second terminal coupled to the positive power supply line;
a first programmable resistor having a first terminal coupled to the first programmable current source and having a second terminal coupled to a node;
a second programmable resistor having a first terminal coupled to the second programmable current source and having a second terminal coupled to the node; and
a third programmable current source having a first terminal coupled to the node and having a second terminal coupled to the positive power supply line.

15. The transconductance circuit of claim 14, wherein:
during a first gain mode configured to produce a first amount of gain, the first and second programmable current sources are fully activated while the third programmable current source is deactivated;
during a second gain mode configured to produce a second amount of gain greater than the first amount of gain, the first and second programmable current sources are deactivated while the third programmable current source is fully activated; and
during a third gain mode configured to produce a third amount of gain greater than the first amount of gain and less than the second amount of gain, the first, second, and third programmable current sources are partially activated.

16. A transconductance circuit comprising:
a first programmable pull-down switch having a gate terminal configured to receive an input signal, wherein the first programmable pull-down switch has a first threshold voltage and is adjusted to provide a first drive strength; and
a second programmable pull-down switch coupled in parallel with the first programmable pull-down switch and having a gate terminal configured to receive the input signal, wherein the second programmable pull-down switch has a second threshold voltage different than the first threshold voltage and is adjusted to provide a second drive strength different than the first drive strength, wherein the transconductance circuit has a linearity that is optimized based on the first and second drive strengths.

17. The transconductance circuit of claim 16, further comprising:
a third programmable pull-down switch coupled in parallel with the first programmable pull-down switch and having a gate terminal configured to receive the input signal, wherein the third programmable pull-down switch has a third threshold voltage different than the first and second threshold voltages and is adjusted to provide a third drive strength different than the first drive strength to optimize the linearity of the transconductance circuit.

18. The transconductance circuit of claim 16, wherein the first programmable pull-down switch comprises:
an array of n-type transistors; and
a plurality of switches each of which is coupled in series with an respective one of the n-type transistors in the array of n-type transistors.

19. The transconductance circuit of claim 16, further comprising:
a programmable current source having a first terminal coupled to the source terminals of the first and second programmable pull-down switches and having a second terminal coupled to a ground line, wherein the programmable current source is activated during a first gain mode and is deactivated during a second gain mode.

20. The transconductance circuit of claim 19, further comprising:
a programmable source degeneration resistor directly coupled to the source terminals of the first and second programmable pull-down switches, wherein the programmable source degeneration resistor is adjusted to provide a first resistance during the first gain mode and to provide a second resistance, less than the first resistance, during the second gain mode.
